(19) United States
(12) Patent Application Publication
(10) Pub. No.: US 2026/0143891 A1
(43) Pub. Date: May 21, 2026

(54) DISPLAY PANEL

(71) Applicant: PlayNitride Display Co., Ltd., MiaoLi County (TW)

(72) Inventors: Hio-Kun Si, MiaoLi County (TW); Hao-Yun Lai, MiaoLi County (TW); Sheng-Yuan Sun, MiaoLi County (TW); Po-Wei Chiu, MiaoLi County (TW)

(73) Assignee: PlayNitride Display Co., Ltd., MiaoLi County (TW)

(21) Appl. No.: 19/227,497

(22) Filed: Jun. 4, 2025

Related U.S. Application Data
(60) Provisional application No. 63/721,565, filed on Nov. 18, 2024.

(30) Foreign Application Priority Data
May 6, 2025 (TW) 114116901

(51) Int. Cl. H10H 29/855; H01L 25/075; H10H 29/856

(52) U.S. Cl. CPC H10H 29/855; H10H 29/8552; H10H 29/856; H10W 90/00

(57) ABSTRACT

A display panel includes a circuit substrate, a patterned structure layer, a plurality of micro light-emitting chips, a plurality of refractive spheres and a filling layer. A plurality of pixel regions are defined on the circuit substrate. The patterned structure layer is disposed on the circuit substrate to separate the pixel regions and form a plurality of accommodating spaces respectively corresponding to the pixel regions. The micro light-emitting chips are connected to the circuit substrate and are respectively disposed in the accommodating spaces corresponding to the pixel regions. The refractive spheres are disposed on a side of the micro light-emitting chips away from the circuit substrate, and each refractive sphere is respectively accommodated in one of the accommodating spaces. In a direction parallel to a surface of the circuit substrate, the filling layer is filled between the patterned structure layer and each refractive sphere.

### CROSS-REFERENCE TO RELATED APPLICATION

This application claims the priority benefit of U.S. provisional application Ser. No. 63/721,565, filed on Nov. 18, 2024, and Taiwan application serial no. 114116901, filed on May 6, 2025. The entirety of each of the above-mentioned patent applications is hereby incorporated by reference herein.

### BACKGROUND

### Technical Field

The disclosure relates to an optoelectronic element, and in particular relates to a display panel.

### Description of Related Art

In display panels utilizing light-emitting chips as pixels, existing panel packaging employing light reflective banks may reduce light crosstalk between pixels and, to some extent, collect divergent light at large angles from the light-emitting chips. However, these methods still have some shortcomings. For example, while light reflective banks may collect divergent light through reflection, they inherently lack light-converging capabilities, providing only indirect and substantially limited effects on enhancing front light emission.

In recent years, the concept of integrating micro lenses within display panels to actively converge light has been proposed. The micro lens is formed through a reflow process applied to patterned photoresist, causing it to coalesce into a lens shape. However, this method is subject to various limitations and disadvantages. These limitations include the requirement for a flat surface to effectively control the shape of the photoresist after reflow, necessitating the application of a planarization layer over the chips. Consequently, the side of the micro lens facing the chip remains flat after formation, resulting in a plano-convex lens; thus, light passing through the micro lens undergoes only one convergence, exhibiting inferior performance compared to a spherical or biconvex lens. Due to insufficient refraction and limitations in refractive index of the materials, the patterned region must substantially cover beyond the range of the chip to achieve noticeable light convergence effects, which is disadvantageous for high pixel density displays. Furthermore, as each sub-pixel requires individual injection of photoresist for the reflow process, this not only results in low efficiency but also presents challenges in maintaining uniform lens dimensions. Additionally, adapting the reflow process for chips of varying sizes necessitates calibration, involving numerous optimization variables and high experimental costs. Moreover, while this packaging process increases the total amount of front light from the display panel, these light rays are effectively distributed across the entire lens, resulting in minimal enhancement of visual brightness.

### SUMMARY

A display panel is provided in the disclosure, in which each pixel region is configured with a refractive sphere to enhance the efficiency of converging light, which may significantly improve the luminance of the display panel. Furthermore, since the area occupied by the refractive sphere is greatly reduced, the disclosure is applicable to display panels that have high requirements on brightness and pixel density (e.g., wearable displays).

The disclosure provides a manufacturing method of a display panel, which incorporates a refractive sphere to replace the aforementioned step of forming a lens through a reflow process, thereby expeditiously completing the lens fabrication and packaging of the display panel. In addition, the manufacturing method has fewer prerequisites or restrictions and has lower optimization design costs.

A display panel is provided in an embodiment of the disclosure. The display panel includes a circuit substrate, a patterned structure layer, multiple micro light-emitting chips, multiple refractive spheres and a filling layer. Multiple pixel regions are defined on the circuit substrate. The patterned structure layer is disposed on the circuit substrate to separate the pixel regions and form multiple accommodating spaces respectively corresponding to the pixel regions. The micro light-emitting chips are connected to the circuit substrate and are respectively disposed in the accommodating spaces corresponding to the pixel regions. The refractive spheres are disposed on a side of the micro light-emitting chips away from the circuit substrate, and each of the refractive spheres is respectively accommodated in one of the accommodating spaces. Each of the refractive spheres has a spherical surface, the spherical surface has a distance from the corresponding micro light-emitting chip on a side facing the corresponding micro light-emitting chip, and the distance increases from a center of the spherical surface to an edge of the spherical surface. In a direction parallel to a surface of the circuit substrate, the filling layer is filled between the patterned structure layer and each of the refractive spheres, and materials of the filling layer, the patterned structure layer and the refractive spheres are all different.

A manufacturing method of a display panel is provided in the disclosure, the manufacturing method includes the following operation. Multiple refractive spheres are provided, in which the refractive spheres have different sizes. A first screening unit and a second screening unit are provided, in which the first screening unit has a first screening size, and the second screening unit has a second screening size greater than or equal to the first screening size. The refractive spheres are placed into the first screening unit to obtain a portion of the refractive spheres having a size greater than the first screening size. A carrier plate is provided, and the second screening unit is combined with the carrier plate, so that the second screening unit forms multiple accommodating spaces on the carrier plate. The refractive spheres having the size greater than the first screening size are placed into the second screening unit, so that the refractive spheres enter the accommodating spaces through the second screening unit.

In the display panel and the manufacturing method thereof of the embodiment of the disclosure, since refractive spheres are utilized as lenses, this facilitates the expeditious completion of lens fabrication for the entire display panel, thereby eliminating the need for photoresist reflow lens and prerequisite planarization layer processes. In addition, for the light from the micro light-emitting chip, the refractive sphere may provide a secondary deflection converging effect. On the basis of effectively improving the luminance of the display panel, the area occupied by the refractive sphere is greatly reduced, thereby taking into account both the brightness and size requirements of micro displays. In addition, compared to the reflow process which may be limited in implementation or increase in complexity due to the size difference of the pixel region, the embodiment of the disclosure may quickly adjust the design by only changing the size of the refractive sphere and the position of the accommodating space, resulting in lower optimization design costs.

### BRIEF DESCRIPTION OF THE DRAWINGS

FIG. 1 is a partial cross-sectional schematic diagram of a display panel of an embodiment of the disclosure.

FIG. 2 is a partial cross-sectional schematic diagram of a display panel of another embodiment of the disclosure.

FIG. 3 is a partial cross-sectional schematic diagram of a display panel of yet another embodiment of the disclosure.

FIG. 4 is a three-dimensional diagram of a patterned structure layer and multiple refractive spheres in a display panel of yet another embodiment of the disclosure.

FIG. 5 is a schematic diagram showing the relative position relationship between the refractive sphere and the micro light-emitting chip in a display panel of another embodiment of the disclosure.

FIG. 6 is a partial cross-sectional schematic diagram of a display panel of yet another embodiment of the disclosure.

FIG. 7 is a partial cross-sectional schematic diagram of a display panel of yet another embodiment of the disclosure.

FIG. 8A to FIG. 8I are schematic diagrams for illustrating the process of a manufacturing method of a display panel of an embodiment of the disclosure.

FIG. 9 is a cross-sectional schematic diagram showing a step of a manufacturing method of a display panel of another embodiment of the disclosure.

FIG. 10A is a three-dimensional schematic diagram showing the relative relationship among the refractive spheres, the patterned structure layer and the accommodating spaces of a display panel of another embodiment of the disclosure.

FIG. 10B is a top view schematic diagram showing the relative relationship between the micro light-emitting chips and the accommodating spaces in the display panel of FIG. 10A.

FIG. 11A is a three-dimensional schematic diagram showing the relative relationship among the refractive spheres, the patterned structure layer and the accommodating spaces of a display panel of another embodiment of the disclosure.

FIG. 11B is a top view schematic diagram showing the relative relationship between the micro light-emitting chips and the accommodating spaces in the display panel of FIG. 11A.

FIG. 12A to FIG. 12E illustrate various possible variations of the step of FIG. 8F.

FIG. 13A to FIG. 13C illustrate various possible variations of the step of FIG. 8H.

### DETAILED DESCRIPTION OF DISCLOSED EMBODIMENTS

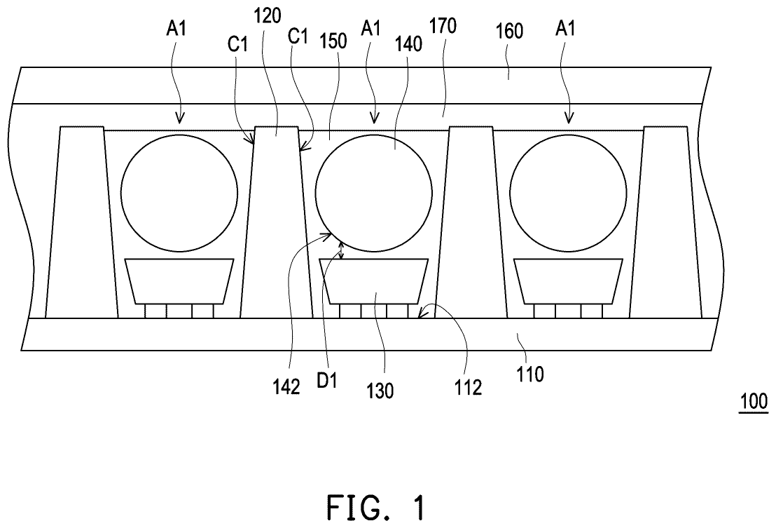

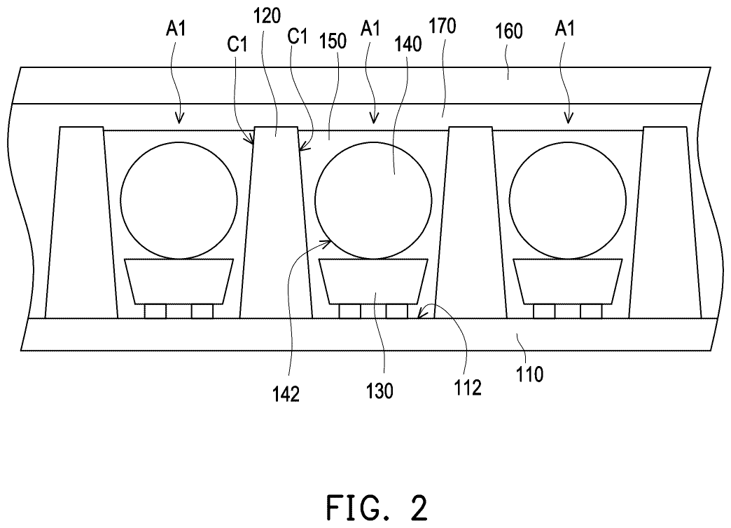

FIG. 1 is a partial cross-sectional schematic diagram of a display panel of an embodiment of the disclosure. Referring to FIG. 1, the display panel 100 of the present embodiment includes a circuit substrate 110, a patterned structure layer 120, multiple micro light-emitting chips 130, multiple refractive spheres 140 and a filling layer 150. Multiple pixel regions A1 are defined on the circuit substrate 110. The patterned structure layer 120 is disposed on the circuit substrate 110 to separate the pixel regions A1 and form multiple accommodating spaces C1 respectively corresponding to the pixel regions A1. The micro light-emitting chips 130 are electrically connected to the circuit substrate 110 and are respectively disposed in the accommodating spaces C1 corresponding to the pixel regions A1. In this embodiment, the micro light-emitting chips 130 are, for example, micro light-emitting diodes. The refractive spheres 140 are disposed on a side of the micro light-emitting chips 130 away from the circuit substrate 110, and each of the refractive spheres 140 is respectively accommodated in one of the accommodating spaces C1. Each of the refractive spheres 140 has a spherical surface 142. The spherical surface 142 has a distance D1 from the micro light-emitting chip 130 on a side facing the corresponding micro light-emitting chip 130. The distance D1 increases from a center of the spherical surface 142 to an edge of the spherical surface 142. In another embodiment, as shown in FIG. 2, each of the refractive spheres 140 directly contacts the corresponding micro light-emitting chip 130, that is, at the center of the spherical surface 142, the distance D1 between the spherical surface 142 and the micro light-emitting chip 130 is 0. In this embodiment, in a direction parallel to the surface 112 of the circuit substrate 110, the filling layer 150 is filled between the patterned structure layer 120 and each of the refractive spheres 140, and the material of the filling layer 150, the material of the patterned structure layer 120 and the materials of the refractive spheres 140 are different and have different refractive indices.

In this embodiment, in a direction perpendicular to the surface 112 of the circuit substrate 110, the filling layer 150 is at least filled between each of the refractive spheres 140 and the corresponding micro light-emitting chip 130. Referring to the example in FIG. 1, the filling layer 150 further encapsulates and covers the refractive sphere 140. In this embodiment, the filling layer 150 is a light-transmissive material, such as a transparent resin, and is at least disposed on a side of each of the spherical surfaces 142 away from the corresponding micro light-emitting chip 130, for example, covering more than half of the height of the refractive sphere 140. The patterned structure layer 120 is a light reflecting layer or a light absorbing layer. For example, a reflective material such as silver (Ag) or aluminum (Al) may be coated on the surface of the patterned structure layer 120, alternatively, a dark-colored molding compound may be used or a light absorbing material such as carbon black may be added to the photoresist so that the patterned structure layer 120 has a light absorbing effect.

In this embodiment, the display panel 100 further includes an optical adhesive layer 170. The optical adhesive layer 170 covers the patterned structure layer 120, the filling layer 150 and the refractive spheres 140. The display panel 100 further includes a light-transmissive substrate 160, which is disposed on a side of the micro light-emitting chips 130 away from the circuit substrate 110 and disposed on the optical adhesive layer 170. In this embodiment, the refractive index of the filling layer 150 is less than the refractive index of the optical adhesive layer 170. In one embodiment, the refractive index of the refractive sphere 140 is between 1.7 and 2, such as 1.9, the refractive index of the optical adhesive layer 170 and the light-transmissive substrate 160 is, for example, 1.5, and the refractive index of the filling layer 150 is, for example, 1.3.

For the light from the micro light-emitting chip 130, the refractive sphere 140 may provide a secondary deflection converging effect due to its upper and lower refractive surfaces. On the basis of effectively improving the luminance of the display panel 100, the area occupied by the refractive sphere 140 is greatly reduced, thereby taking into account the high brightness and small size requirements of the display panel 100.

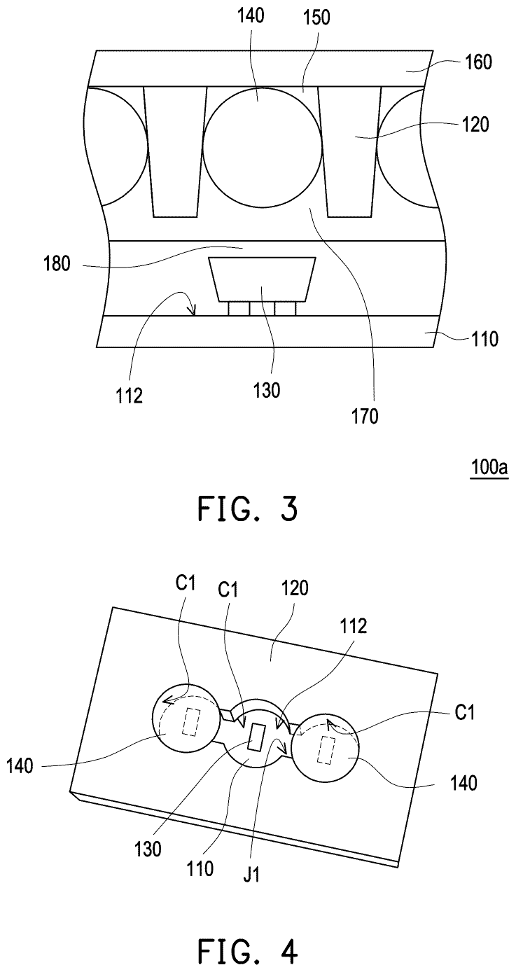

FIG. 3 is a partial cross-sectional schematic diagram of a display panel of yet another embodiment of the disclosure. Referring to FIG. 3, the display panel 100a of this embodiment is similar to the display panel 100 of FIG. 1, and the main differences between the two are as follows. In the display panel 100a of the present embodiment, the light-transmissive substrate 160 is disposed on a side of the micro light-emitting chips 130 away from the circuit substrate 110, and the patterned structure layer 120 is connected to the light-transmissive substrate 160. In addition, in this embodiment, the optical adhesive layer 170 is disposed between the patterned structure layer 120 and the micro light-emitting chips 130. Furthermore, in this embodiment, the display panel 100a further includes a planarization layer 180 covering the micro light-emitting chips 130, and the planarization layer 180 is disposed between the optical adhesive layer 170 and the circuit substrate 110.

In this embodiment, each of the refractive spheres 140 directly contacts the light-transmissive substrate 160. In addition, in a direction perpendicular to the surface 112 of the circuit substrate 110, the filling layer 150 is filled between each refractive sphere 140 and the light-transmissive substrate 160.

The manufacturing method of the display panel 100a includes providing the light-transmissive substrate 160 and the circuit substrate 110, and forming the patterned structure layer 120 on the light-transmissive substrate 160. Then, after the refractive spheres 140 enter the accommodating spaces C1, the refractive spheres 140 are sealed between the light-transmissive substrate 160 and the circuit substrate 110. Specifically, multiple micro light-emitting chips 130 may be disposed on the circuit substrate 110, and then the micro light-emitting chips 130 may be covered with the planarization layer 180. Next, the optical adhesive layer 170 is coated on the planarization layer 180, and then the light-transmissive substrate 160 is turned over to combine the patterned structure layer 120 and the refractive spheres 140 with the optical adhesive layer 170, thereby sealing the refractive spheres 140 between the light-transmissive substrate 160 and the circuit substrate 110.

FIG. 4 is a three-dimensional diagram of a patterned structure layer and multiple refractive spheres in a display panel of yet another embodiment of the disclosure. Referring to FIG. 4, in this embodiment, in a viewing angle perpendicular to the surface 112 of the circuit substrate 110, the patterned structure layer 120 conformally surrounds the refractive spheres 140. In FIG. 4, in order to clearly illustrate the relationship among the patterned structure layer 120, the micro light-emitting chips 130 and the refractive spheres 140, the refractive sphere 140 in the central accommodating space C1 is not shown.

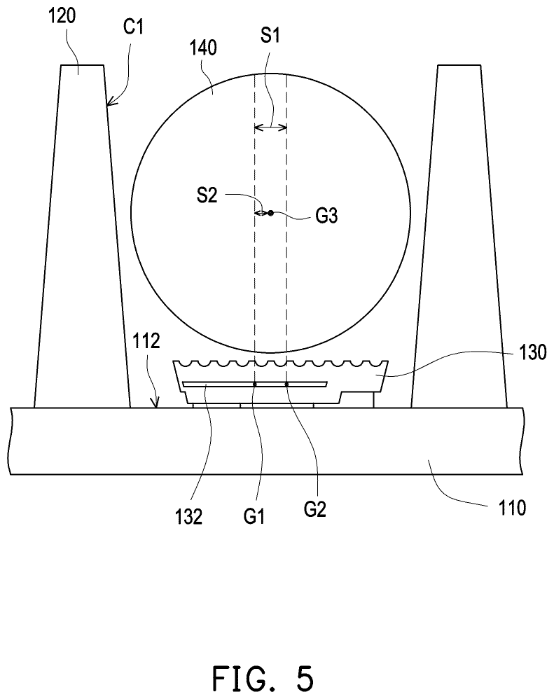

FIG. 5 is a schematic diagram showing the relative position relationship between the refractive sphere and the micro light-emitting chip in a display panel of another embodiment of the disclosure. Referring to FIG. 5, each of these micro light-emitting chips 130 has a light-emitting layer 132 parallel to the circuit substrate 110. In a direction parallel to the surface 112 of the circuit substrate 110, the geometric center G1 of at least a portion of the light-emitting layer 132 has a first offset S1 relative to the geometric center G2 of the micro light-emitting chip 130, and has a second offset S2 relative to the geometric center G3 of the accommodating space C1. The first offset S1 is greater than the second offset S2, and the second offset S2 is preferably 0. Specifically, for example, in a lateral chip or a flip chip, a portion of the light-emitting layer 132 may be removed due to process factors, resulting in the geometric center G1 not coinciding with the geometric center G2. In this embodiment, the position of the geometric center G3 of the accommodating space C1 may be controlled by adjusting the exposure region of the patterned structure layer 120. In this way, the center of the refractive sphere 140 may be aligned with the geometric center G1 of the light-emitting layer 132 as much as possible, so that the light emission efficiency may be maximized.

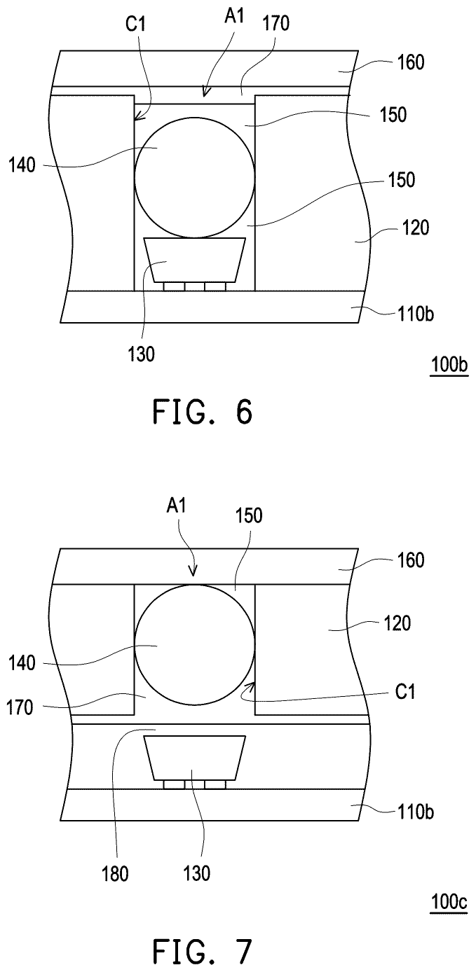

FIG. 6 is a partial cross-sectional schematic diagram of a display panel of yet another embodiment of the disclosure. Referring to FIG. 6, the display panel 100b of this embodiment is similar to the display panel 100 of FIG. 1, and the main differences between the two are as follows. In the display panel 100 of FIG. 1, the circuit substrate 110 is an opaque substrate, while in the display panel 100b of this embodiment, the circuit substrate 110b is a transparent substrate, so that the display panel 100b becomes a transparent display panel.

FIG. 7 is a partial cross-sectional schematic diagram of a display panel of yet another embodiment of the disclosure. Referring to FIG. 7, the display panel 100c of this embodiment is similar to the display panel 100a of FIG. 3, and the main differences between the two are as follows. In the display panel 100a of FIG. 3, the circuit substrate 110 is an opaque substrate, while in the display panel 100c of this embodiment, the circuit substrate 110b is a transparent substrate, so that the display panel 100c becomes a transparent display panel.

The main difference between the embodiments of FIG. 6 and FIG. 7 compared to FIG. 1 and FIG. 3 is that the circuit substrate 110b used in the embodiments of FIG. 6 and FIG. 7 is applicable to a transparent display. In order to further improve the light transmittance of the display panel 100b and the display panel 100c, the patterned structure layer 120 is a light-transmissive layer. In the embodiments of FIG. 6 and FIG. 7, the patterned structure layer 120 is, for example, a light-transmissive material, and the refractive index of the filling layer 150 is less than the refractive index of the patterned structure layer 120.

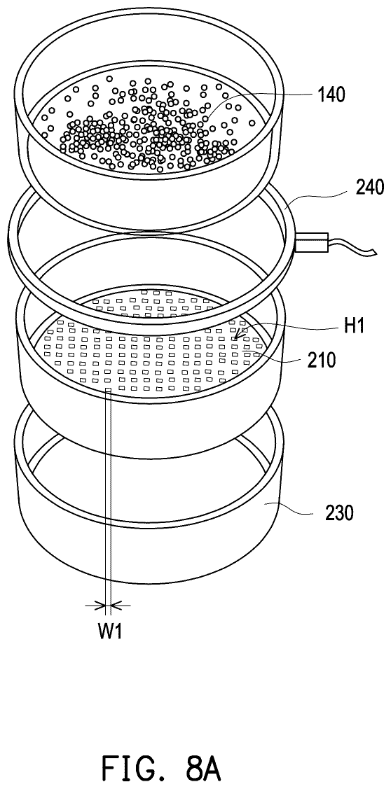

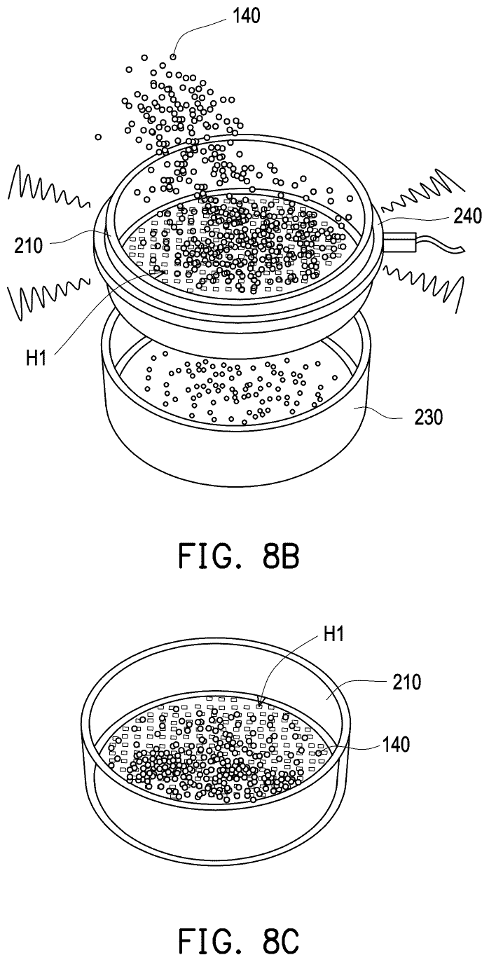

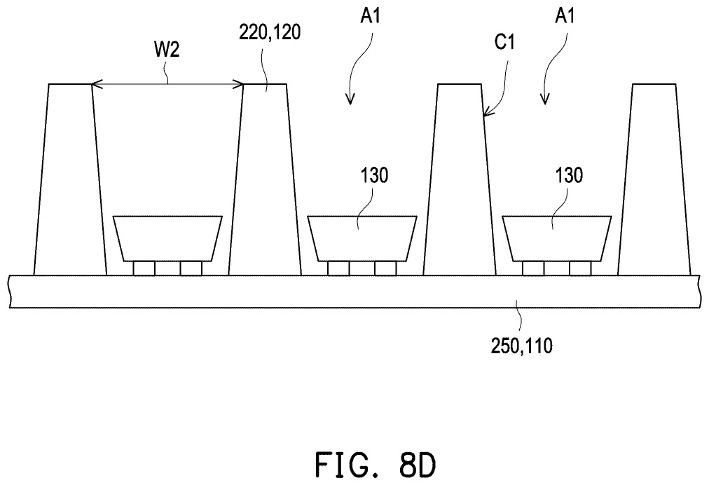

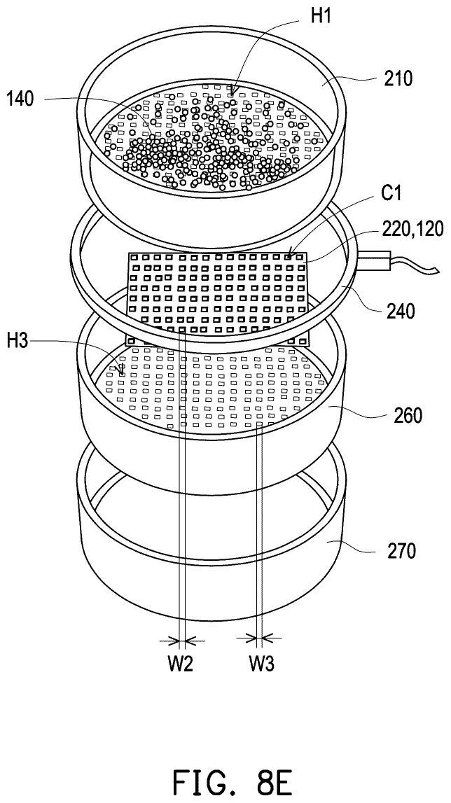

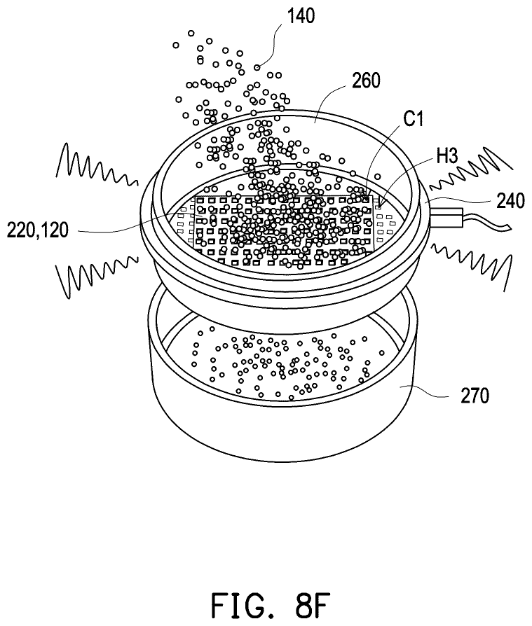

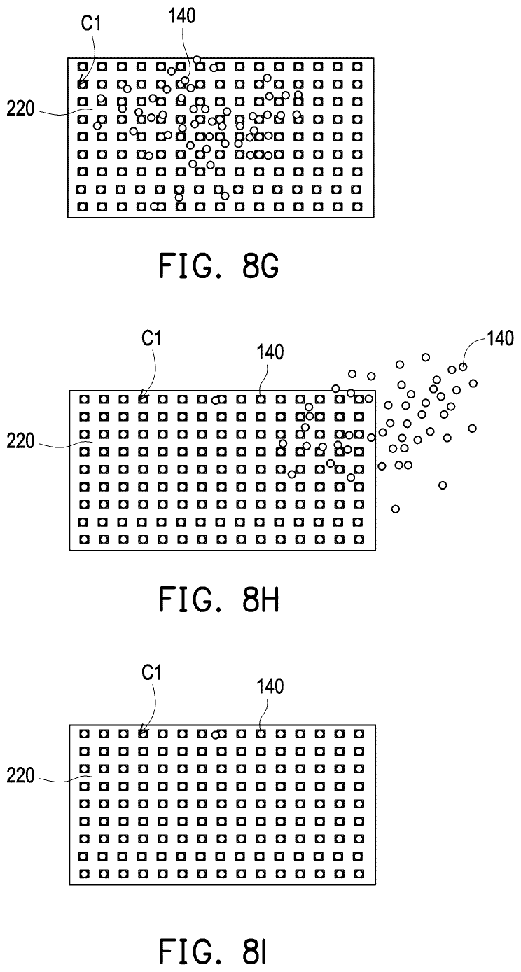

FIG. 8A to FIG. 8I are schematic diagrams for illustrating the process of a manufacturing method of a display panel of an embodiment of the disclosure. FIG. 8A to FIG. 8C, FIG. 8E and FIG. 8F are three-dimensional schematic diagrams, FIG. 8D is a cross-sectional schematic diagram, and FIG. 8G to FIG. 8I are top view schematic diagrams. Referring to FIG. 8A to FIG. 8I, the manufacturing method of the display panel of this embodiment may be used to manufacture the display panels of the above embodiments, and the following explanation is provided taking the manufacturing of the aforementioned display panel 100 as an example. The manufacturing method of the display panel of this embodiment includes the following steps. Firstly, as shown in FIG. 8A, multiple refractive spheres 140 are provided. The refractive spheres 140 have different sizes, for example, different diameters. In this embodiment, the diameter of the refractive sphere 140 is, for example, in the range of 30 microns to 50 microns. In addition, a first screening unit 210 and a second screening unit 220 are provided (as shown in FIG. 8D and FIG. 8E). The first screening unit 210 has a first screening size W1, and the second screening unit 220 has a second screening size W2 greater than or equal to the first screening size W1. The first screening size W1 and the second screening size W2 are, for example, the width of a hole. Then, as shown in FIG. 8B, these refractive spheres 140 are placed in the first screening unit 210 to obtain a portion of the refractive spheres 140 having dimensions of the first screening size W1 or greater. In this embodiment, the first screening size W1 is, for example, 38 microns. Therefore, in the step of FIG. 8B, the refractive spheres 140 with a diameter greater than 38 microns may be obtained, while refractive spheres 140 with a diameter less than 38 microns pass through the holes H1 of the first screening unit 210 and fall into the bottom plate 230. As shown in FIG. 8C, after the step of FIG. 8B, the refractive spheres 140 with a diameter greater than 38 microns cannot pass through the holes of the first screening size W1 and are retained in the first screening unit 210. The manufacturing method of the display panel of the present embodiment further includes providing an oscillating unit 240. When the refractive spheres 140 are placed in the first screening unit 210, the oscillating unit 240 is activated so that the oscillating unit 240 acts upon the first screening unit 210. The oscillating unit 240 is, for example, an ultrasonic vibration holder, and the oscillation frequency is, for example, 10 to 2000 Hz. When the oscillating unit 240 is activated, it may drive the first screening unit 210 to vibrate, which helps to eliminate the influence of static electricity or friction, so that the refractive spheres 140 with a diameter less than 38 microns may smoothly pass through the hole H1 of the first screening unit 210 and fall into the bottom plate 230.

On the other hand, as shown in FIG. 8D, a carrier plate 250 is provided, and the second screening unit 220 is combined with the carrier plate 250, so that the second screening unit 220 forms multiple accommodating spaces C1 on the carrier plate 250. That is, since the patterned structure layer 120 is formed by a patterning process, the hole diameter of the accommodating spaces C1 may accurately and consistently conform to the second screening size W2. Therefore, in this embodiment, the second screening unit 220 may be directly replaced by a patterned structure layer 120 in FIG. 1. Specifically, the carrier plate 250 is, for example, the circuit substrate 110 of FIG. 1. After a patternable photoresist material is coated on the carrier plate 250, a patterning process is performed with a second screening size W2 to form a patterned structure layer 120 with the second screening size W2. In this embodiment, the circuit substrate 110 has multiple pixel regions A1 corresponding to the accommodating spaces C1. Each of the pixel regions A1 is provided with at least one micro light-emitting chip 130, and the second screening unit 220 exposes the micro light-emitting chips 130 through a patterning process.

Afterwards, as shown in FIG. 8E and FIG. 8F, the refractive spheres 140 having a size greater than the first screening size W1 are placed into the second screening unit 220, so that the refractive spheres 140 enter the accommodating spaces C1 through the second screening unit 220. Following the above, the second screening size W2 is greater than 38 microns (e.g., 42 microns). When the refractive spheres 140 with a diameter greater than 38 microns are placed on the second screening unit 220, the oscillating unit 240 is activated so that the oscillating unit 240 acts upon the second screening unit 220. As a result, only the refractive spheres 140 with a diameter of 38 microns to 42 microns enter the accommodating spaces C1. As shown in FIG. 8G, a portion of the refractive spheres 140 that has not entered or cannot enter the accommodating spaces C1 remains on the second screening unit 220. In the step of FIG. 8H, the refractive spheres 140 remaining on the second screening unit 220 that have not entered or are unable to enter the accommodating spaces C1 may be removed. Finally, as shown in FIG. 8I, the step of placing the refractive spheres 140 into the accommodating spaces C1 is completed.

Referring to FIG. 8E and FIG. 8F again, the manufacturing method of the display panel of this embodiment may further include the following steps. First, as shown in FIG. 8E, a third screening unit 260 is provided, which has a third screening size W3 greater than the second screening size W2. Then, as shown in FIG. 8F, the second screening unit 220 and the carrier plate 250 are placed into the third screening unit 260. In addition, a recycling unit 270 is provided and disposed at one side of the third screening unit 260 to recycle the refractive spheres 140 that have not entered the pixel regions A1. For example, in this embodiment, the third screening size W3 is, for example, 100 microns, which is, for example, the width of the hole H3 of the third screening unit 260. Such a size is suitable for allowing all the refractive spheres 140 that have not entered the pixel region A1 to pass through and be recycled by the recycling unit 270. The recycling unit 270 is, for example, a recycling basin. When the oscillating unit 240 is activated, it may drive the third screening unit 260 to vibrate, thereby driving the second screening unit 220 to vibrate, so that the refractive spheres 140 with approximately the second screening size fall into the accommodating spaces C1, and the excess refractive spheres that do not fall into the accommodating spaces C1 pass through the holes H3 of the third screening unit 260 and are recycled by the recycling unit 270.

Referring to FIG. 1 again, in this embodiment, after the refractive spheres 140 are placed in the accommodating spaces C1, the manufacturing method of the display panel further includes providing a filling layer 150 to the accommodating spaces C1, so that the filling layer 150 is filled between the refractive spheres 140, the second screening unit 220 (i.e., the patterned structure layer 120) and the carrier plate 250 (e.g., the circuit substrate 110). In the embodiment as shown in FIG. 4, at least a portion of the accommodating spaces C1 are connected to each other (In FIG. 4, every three connected to each other are taken as an example), and the filling layer 150 (i.e., the transparent material filled in the accommodating spaces C1, not shown in FIG. 4) is also integrally connected in the connected accommodating spaces C1. For example, the material of the filling layer 150 may be dripped into the connecting channel J1 between two adjacent accommodating spaces C1, thereby filling the spaces and the connecting channels J1 between the refractive spheres 140, the patterned structure layer 120 and the circuit substrate 110, so that the cured filling layer 150 is integrally connected in the connected accommodating spaces C1. In addition, in FIG. 4, the three micro light-emitting chips 130 in the three accommodating spaces C1 interconnected by the connecting channels J1 may be a red light micro light-emitting chip 130, a green light micro light-emitting chip 130, and a blue light micro light-emitting chip, respectively, and the sizes of the three micro light-emitting chips 130 may be the same or different. When the sizes of the three micro light-emitting chips 130 are different, the sizes of the three accommodating spaces C1 (i.e., the determined exposure region of the patterned structure layer 120) may also vary with the sizes of the three micro light-emitting chips 130 due to the optical pattern conditions, and thus the sizes of the refractive spheres 140 placed in the three accommodating spaces C1 of different sizes may also be different accordingly. For example, three refractive spheres 140 of different sizes are selected and placed into the accommodating space C1 from large to small. In this way, it may be ensured that the accommodating spaces C1 may all accommodate the refractive spheres 140 of corresponding sizes, thereby preventing the small-sized refractive sphere 140 from being placed in the large accommodating space C1.

Afterwards, referring to FIG. 1 again, the patterned structure layer 120, the filling layer 150 and the refractive spheres 140 are covered with the optical adhesive layer 170. In another embodiment, the filling layer 150 may not be used, but the optical adhesive layer 170 may be directly filled between the refractive spheres 140, the patterned structure layer 120 and the circuit substrate 110, and the optical adhesive layer 170 may cover the patterned structure layer 120, the filling layer 150 and the refractive spheres 140. In this case, in one embodiment, the refractive index of the optical adhesive layer 170 is, for example, 1.5, but the disclosure is not limited thereto. Compared with not using the filling layer 150, which would allow air to exist between the refractive spheres 140, the patterned structure layer 120 and the circuit substrate 110, the aforementioned use of the filling layer 150 or the optical adhesive layer 170 to fill these spaces may further enhance the light emission efficiency.

Afterwards, the light-transmissive substrate 160 is disposed on the optical adhesive layer 170, and the manufacturing of the display panel 100 is completed.

In the manufacturing method of the display panel of the present embodiment, the lens is formed by placing the refractive sphere 140 to replace the photoresist reflow process in the prior art, so that the prerequisite planarization layer process is not required, enabling rapid completion of the lens manufacturing of the entire display panel 100. In addition, compared with the prior art, the refractive sphere 140 has two opposite refractive surfaces (i.e., the upper half and the lower half of the spherical surface 142 in FIG. 1), which may effectively improve the luminance of the display panel 100. Since the light converging effect is effectively improved, the refractive sphere 140 does not need to substantially cover beyond the range of the micro light-emitting chip 130. Therefore, the manufacturing method of the display panel of this embodiment may be applied to manufacturing a display panel 100 with a higher pixel density. In addition, the size and position of the refractive sphere 140 may be quickly changed, so the manufacturing method of the display panel of this embodiment may have a lower optimization design cost.

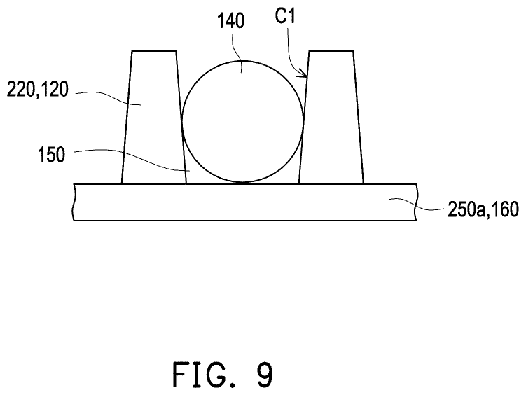

FIG. 9 is a cross-sectional schematic diagram showing a step of a manufacturing method of a display panel of another embodiment of the disclosure. Referring to FIG. 9 and FIG. 3, the manufacturing method of the display panel of the present embodiment is similar to the manufacturing method of the display panel of FIG. 8A to FIG. 8I, and the main differences between the two are as follows. In the manufacturing method of the display panel of the present embodiment, as shown in FIG. 9, the carrier plate 250a is an intermediate carrier plate, which is, for example, a light-transmissive substrate 160, and a second screening unit 220 (i.e., a patterned structure layer 120) may be disposed thereon. After the refractive spheres 140 enter the accommodating spaces C1, a filling layer 150 may be provided so that the filling layer 150 is filled between the refractive spheres 140, the second screening unit 220 (i.e., the patterned structure layer 120), and the carrier plate 250 (i.e., the light-transmissive substrate 160). After the filling layer 150 is cured, the refractive sphere 140 is fixed on the light-transmissive substrate 160. In the next step, the step of turning the carrier plate 250a (the light-transmissive substrate 160) and combining the carrier plate 250a with the circuit substrate 110 as described in the embodiment of FIG. 3 may be applied.

Compared with not using the filling layer 150, which would allow air to exist between the refractive spheres 140, the patterned structure layer 120 and the carrier plate 250a, the aforementioned use of the filling layer 150 or the optical adhesive layer 170 to fill this space may prevent the unexpected influence of air on the deflection path of the light, further enhancing the light emission efficiency. Here, it is preferred to select a more fluid filling layer 150 (e.g., refractive index 1.3) to minimize the air remaining between the carrier plate 250a (i.e., the light-transmissive substrate 160) and the refractive sphere 140 due to the lower fluidity of the optical adhesive layer 170 (e.g., refractive index 1.5).

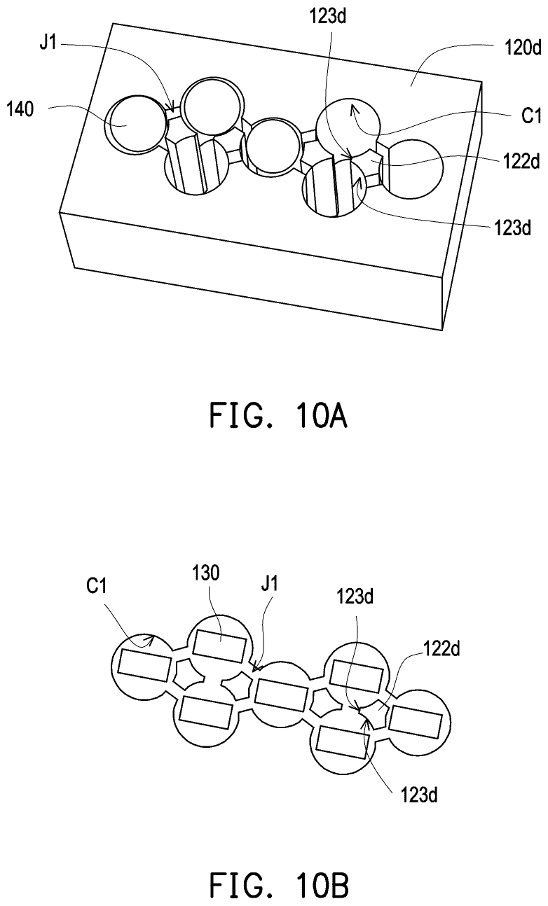

FIG. 10A is a three-dimensional schematic diagram showing the relative relationship among the refractive spheres, the patterned structure layer and the accommodating spaces of a display panel of another embodiment of the disclosure. FIG. 10B is a top view schematic diagram showing the relative relationship between the micro light-emitting chips and the accommodating spaces in the display panel of FIG. 10A. Referring to FIG. 10A and FIG. 10B, the display panel of this embodiment is similar to the display panel of the embodiment of FIG. 4, and the main differences between the two are as follows. In the display panel of the present embodiment, the patterned structure layer 120d further includes an island structure 122d having an independent peripheral sidewall 123d. Each of the refractive spheres 140 is correspondingly disposed in the accommodating space C1, and a connecting channel J1 is disposed between any two adjacent accommodating spaces C1. A portion of the peripheral sidewall 123d may serve as the sidewall of the accommodating space C1, which may contact the refractive sphere 140 and confine the refractive sphere 140 in the accommodating space C1, while another portion of the peripheral sidewall 123d may serve as the sidewall of the connecting channel J1.

The width of the connecting channel J1 may be less than the diameter of the refractive sphere 140 to prevent the refractive sphere 140 from falling in. There is no micro light-emitting chip 130 under the connecting channel J1, which may be exposed by the refractive sphere 140 to serve as a dripping inlet for the material of the filling layer 150. Since the material of the filling layer 150 is fluid, it flows into each of the accommodating spaces C1 through the connecting channel J1, and the filling layer 150 exists in each of the accommodating spaces C1 and is integrally connected with each of the connecting channels J1.

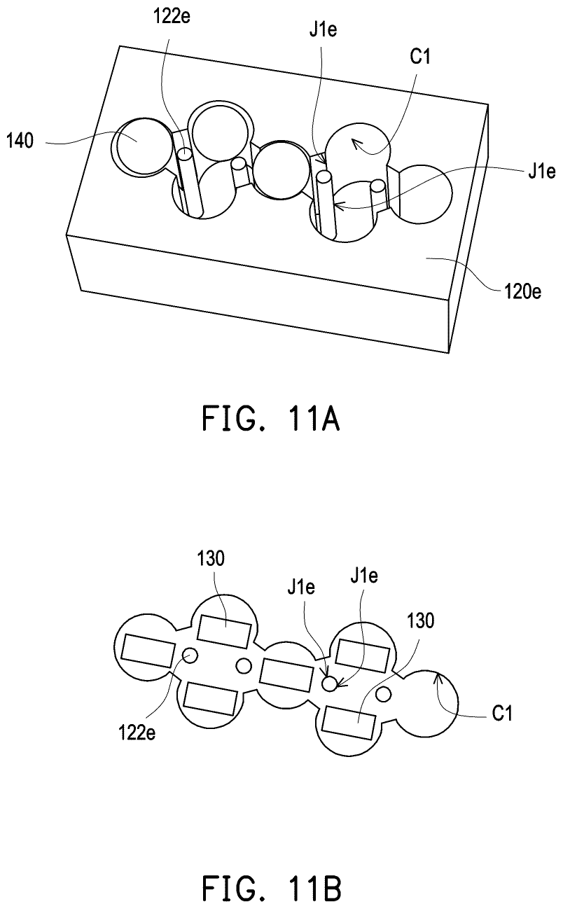

FIG. 11A is a three-dimensional schematic diagram showing the relative relationship among the refractive spheres, the patterned structure layer and the accommodating spaces of a display panel of another embodiment of the disclosure. FIG. 11B is a top view schematic diagram showing the relative relationship between the micro light-emitting chips and the accommodating spaces in the display panel of FIG. 11A. Referring to FIG. 11A and FIG. 11B, the display panel of this embodiment is similar to the display panel of the embodiment of FIG. 10A, and the main differences between the two are as follows. In the display panel of this embodiment, the island structure 122e of the patterned structure layer 120e is columnar, for example cylindrical, and its volume is less than that of the island structure 122d in FIG. 10A, but the width of the connecting channel J1e is still less than the diameter of the refractive sphere 140. In addition, the present embodiment does not limit the micro light-emitting chip 130 to be disposed in each of the accommodating spaces C1. For example, the micro light-emitting chip 130 is not disposed in the rightmost accommodating space C1 in FIG. 11B.

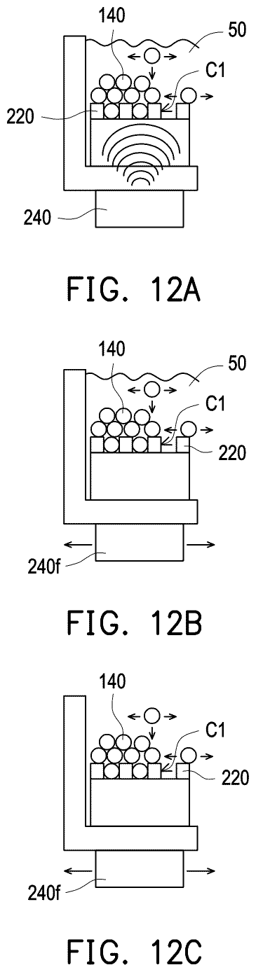

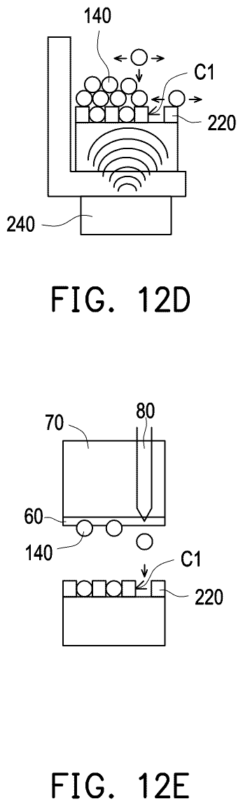

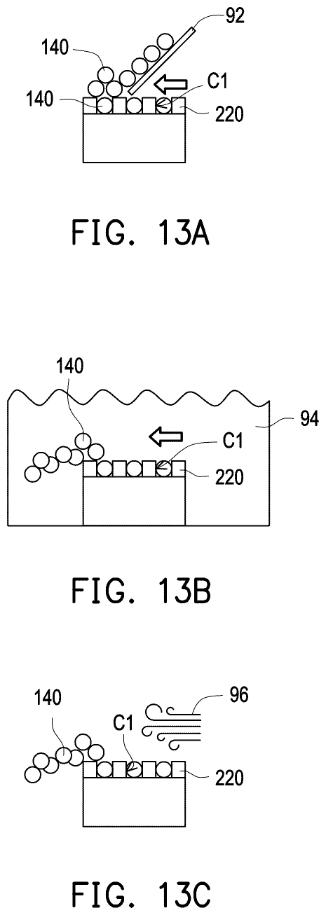

FIG. 12A to FIG. 12E illustrate various possible variations of the step of FIG. 8F. FIG. 13A to FIG. 13C illustrate various possible variations of the step of FIG. 8H. Referring to FIG. 12A first, in this embodiment, the refractive spheres 140 may be placed in the liquid 50, and the oscillating unit 240 drives the second screening unit 220 to oscillate through ultrasonic oscillation to achieve the effect of fluid ultrasonic vibration, so that the refractive spheres 140 of appropriate sizes fall into the accommodating spaces C1 of the second screening unit 220. Referring to FIG. 12B again, which is similar to the embodiment of FIG. 12A, the main difference between the two is that the oscillating unit 240 is replaced by a shaker 240f. The shaking of the shaker 240f drives the second screening unit 220 to oscillate, achieving the effect of fluid physical oscillation, so that the refractive spheres 140 of appropriate sizes fall into the accommodating spaces C1 of the second screening unit 220. Referring to FIG. 12C, this embodiment is similar to the embodiment of FIG. 12B, both using a shaker 240f, but the refractive spheres 140 are in the air rather than in the liquid 50, thereby achieving the effect of dry powder physical oscillation. Referring to FIG. 12D, this embodiment is similar to the embodiment of FIG. 12A, both using ultrasonic oscillation, but the refractive spheres 140 are in the air rather than in the liquid 50, thereby achieving the effect of dry powder ultrasonic oscillation. Referring to FIG. 12E, in this embodiment, the refractive spheres 140 are attached to a temporary substrate 70 via an adhesive layer 60, and a laser beam 80 is focused on the adhesive layer 60 to achieve a debonding effect, so that the refractive spheres 140 fall into the accommodating spaces C1. That is, in addition to using the physical vibration method shown in FIG. 12A to FIG. 12D to place the refractive spheres 140 within each of the accommodating spaces C1, for the few missed accommodating spaces C1, a laser mass repair technology may also be used to transfer the refractive spheres 140 to the accommodating spaces C1 at specific positions.

Referring to FIG. 13A, in this embodiment, a scraper 92 may be used to scrape off the excess refractive spheres 140 that have not entered or cannot enter the accommodating spaces C1. Referring to FIG. 13B, in this embodiment, the propulsive force of the fluid 94 (e.g., liquid) may be used to push away and remove the excess refractive spheres 140 that have not entered or cannot enter the accommodating spaces C1. Referring to FIG. 13C, in this embodiment, the propulsive force of the airflow 96 may be used to blow away and remove the excess refractive spheres 140 that have not entered or cannot enter the accommodating spaces C1.

To sum up, in the display panel and the manufacturing method thereof of the embodiment of the disclosure, since refractive spheres are utilized as lenses, this facilitates the expeditious completion of lens fabrication for the entire display panel, thereby eliminating the need for photoresist reflow lens and prerequisite planarization layer processes. In addition, for the light from the micro light-emitting chip, the refractive sphere may provide a secondary deflection converging effect. On the basis of effectively improving the luminance of the display panel, the area occupied by the refractive sphere is greatly reduced, thereby taking into account both the brightness and size requirements of micro displays. In addition, compared to the reflow process which may be limited in implementation or increase in complexity due to the size difference of the pixel region, the embodiment of the disclosure may quickly adjust the design by only changing the size of the refractive sphere and the position of the accommodating space, resulting in lower optimization design costs.

What is claimed is:

1. A display panel, comprising:
a circuit substrate, wherein a plurality of pixel regions are defined on the circuit substrate;
a patterned structure layer, disposed on the circuit substrate to separate the pixel regions and form a plurality of accommodating spaces respectively corresponding to the pixel regions;
a plurality of micro light-emitting chips, connected to the circuit substrate and respectively disposed in the accommodating spaces corresponding to the pixel regions;
a plurality of refractive spheres, disposed on a side of the micro light-emitting chips away from the circuit substrate, wherein each of the refractive spheres is respectively accommodated in one of the accommodating spaces, wherein each of the refractive spheres has a spherical surface, the spherical surface has a distance from the corresponding micro light-emitting chip on a side facing the corresponding micro light-emitting chip, and the distance increases from a center of the spherical surface to an edge of the spherical surface; and
a filling layer, wherein the filling layer is filled between the patterned structure layer and each of the refractive spheres in a direction parallel to a surface of the circuit substrate, and materials of the filling layer, the patterned structure layer and the refractive spheres are all different.

2. The display panel according to claim 1, wherein each of the refractive spheres directly contacts the corresponding micro light-emitting chip.

3. The display panel according to claim 1, wherein the filling layer is at least filled between each of the refractive spheres and the corresponding micro light-emitting chip in a direction perpendicular to the surface of the circuit substrate.

4. The display panel according to claim 1, further comprising a light-transmissive substrate, disposed on the side of the micro light-emitting chips away from the circuit substrate, wherein the patterned structure layer is connected to the light-transmissive substrate.

5. The display panel according to claim 4, further comprising an optical adhesive layer, disposed between the patterned structure layer and the micro light-emitting chips.

6. The display panel according to claim 5, further comprising a planarization layer covering the micro light-emitting chips, wherein the planarization layer is disposed between the optical adhesive layer and the circuit substrate.

7. The display panel according to claim 4, wherein each of the refractive spheres directly contacts the light-transmissive substrate.

8. The display panel according to claim 4, wherein the filling layer is filled between each of the refractive spheres and the light-transmissive substrate in a direction perpendicular to the surface of the circuit substrate.

9. The display panel according to claim 1, wherein the filling layer is a light-transmissive material and is at least disposed on a side of each of the spherical surfaces away from the corresponding micro light-emitting chip.

10. The display panel according to claim 9, wherein the patterned structure layer is a light-transmissive material, and a refractive index of the filling layer is less than a refractive index of the patterned structure layer.

11. The display panel according to claim 1, wherein the patterned structure layer is a light reflecting layer, a light absorbing layer or a light-transmissive layer.

12. The display panel according to claim 1, wherein the patterned structure layer conformally surrounds the refractive spheres in a viewing angle perpendicular to the surface of the circuit substrate.

13. The display panel according to claim 1, wherein each of the micro light-emitting chips has a light-emitting layer parallel to the circuit substrate, a geometric center of at least a portion of the light-emitting layer has a first offset relative to a geometric center of the corresponding micro light-emitting chip, and has a second offset relative to a geometric center of the corresponding accommodating space in the direction parallel to the surface of the circuit substrate, and the first offset is greater than the second offset.
